(19) United States
(12) Patent Application Publication
(10) Pub. No.: US 2025/0112552 A1
(43) Pub. Date: Apr. 3, 2025

(54) POWER-ON-RESET CIRCUIT WITH BROWN-OUT DETECTION

(71) Applicant: Texas Instruments Incorporated, Dallas, TX (US)

(72) Inventor: Hongcheng Xu, Freising (DE)

(21) Appl. No.: 18/477,721

(22) Filed: Sep. 29, 2023

(51) Int. Cl. H02M 3/158; G06F 1/24; H02M 1/00; H02M 1/088

(52) U.S. Cl. CPC H02M 3/158; G06F 1/24; H02M 1/0016; H02M 1/088

(57) ABSTRACT

A voltage monitoring circuit is configured to monitor the input voltage in a power converter and to assert a reset signal to disable operation of the power converter in response to the input voltage falling below a threshold level. The voltage monitoring circuit may include a power-on-reset (POR) block that asserts the reset signal in response to the input voltage falling below a first threshold at a first rate, and a brown-out block that asserts the reset signal in response to the input voltage falling below a second threshold at a faster second rate (e.g., the input voltage falls quickly to zero or near zero such as during a brown-out event). The brown-out block includes a backup supply voltage that maintains some positive voltage level even in the absence of the input voltage for a certain period of time and a discharge circuit designed to quickly assert the reset signal.

### TECHNICAL FIELD

This description relates to power converters, and more particularly, to providing a power-on-reset circuit in a power converter.

### BACKGROUND

Power converters (such as DC-DC converters) are widely used in electronic systems such as consumer electronics, automotive systems, industrial equipment, lighting systems, etc. for converting an input voltage to an output voltage higher or lower than the input voltage. Such converters oftentimes utilize a metal oxide semiconductor field effect transistor (MOSFET) as a power switch that turns on and off to regulate the output voltage. A feedback loop along with a controller is also used to determine the on or off time of the transistor in each switching cycle based on the feedback voltage representative of the power converter output voltage, and a reference voltage, thereby regulating the output voltage of the power converter. Some power converters include two or more such power switches, which may be controlled in a complementary fashion to provide a desired output voltage. For example, some power converters include a high-side power switch and a low-side power switch, which are switched on and off in a pulse width modulation (PWM) scheme provisioned by the controller. Supervision of the input voltage to the power converter often includes monitoring multiple voltage levels to ensure the input voltage is not too low or too high.

### SUMMARY

According to an embodiment, a circuit includes an input supply voltage terminal, an output control voltage terminal, a power-on-reset (POR) circuit coupled to the input supply voltage terminal, and a brown-out detection circuit coupled to the input supply voltage terminal and the output control voltage terminal. The POR circuit includes a POR circuit output coupled to the output control voltage terminal. The brown-out detection circuit includes a back-up supply voltage input. The brown-out detection circuit is configured to discharge the output control voltage terminal to a reset state, responsive to a difference in potential between the back-up supply voltage input and the input supply voltage terminal exceeding a threshold voltage.

According to another embodiment, a controller includes a pulse width modulation circuit configured to determine a switching element duty cycle for a power converter based on a comparison between a reference voltage and a feedback voltage representative of an output voltage of the power converter, and a voltage monitoring circuit. The voltage monitoring circuit includes a reset block, a brown-out detection block, a supply block, and an output circuit. The reset block includes a first transistor coupled between an input supply voltage terminal and a resistor with the resistor coupled between the first transistor and a control output. The brown-out detection block includes a second transistor and a discharge module. The second transistor has a control terminal coupled to the input supply voltage terminal, and the discharge module is configured to discharge voltage at the control output to a ground terminal. The supply block has a third transistor coupled to the input supply voltage terminal and to the second transistor. The output circuit is coupled to the control output and is configured to provide an enable signal for the controller.

According to another embodiment, a voltage monitoring circuit includes a first block configured to assert a first control signal on a control output responsive to an input voltage on an input supply voltage rail terminal falling below a first threshold at a first rate, a second block configured to assert a second control signal on the control output responsive to the input voltage on the input supply voltage rail terminal falling below a second threshold at a second rate faster than the first rate, and an output circuit coupled to the control output and configured to assert a reset signal based on the first or second control signal.

### BRIEF DESCRIPTION OF THE DRAWINGS

FIG. 1 is a block diagram of a voltage regulator with a voltage monitoring circuit, in an example.

FIG. 2A is a schematic diagram of the voltage monitoring circuit illustrated in FIG. 1, in an example.

FIG. 2B is a more detailed schematic diagram of the voltage monitoring circuit illustrated in FIG. 1, in an example.

FIG. 3 illustrates the change in various voltage levels within the voltage monitoring circuit during a brown-out event, in an example.

FIG. 4 illustrates the change in various voltage levels within the voltage monitoring circuit and the assertion of a result signal during a brown-out event, in an example.

### DETAILED DESCRIPTION

A voltage monitoring circuit is described. In an example, the circuit is configured to monitor the input voltage in a power converter (e.g., a DC-DC buck converter). The voltage monitoring circuit may be designed to assert a reset signal to disable operation of the power converter in response to the input voltage falling below a threshold level. The voltage monitoring circuit may include a power-on-reset (POR) block that is arranged to assert the reset signal in response to the input voltage falling below a first threshold at a first rate, and a brown-out block that is arranged to assert the reset signal in response to the input voltage falling below a second threshold at a faster second rate (e.g., the input voltage falls quickly to zero or near zero such as during a brown-out event). The POR block includes a reference voltage source and compares the input voltage to the reference voltage source to determine when to assert the reset signal. The brown-out block includes a backup supply voltage that maintains some positive voltage level even in the absence of the input voltage for a certain period of time and a discharge circuit designed to quickly assert the reset signal in response to a difference in potential between the back-up supply voltage and the input voltage exceeding a threshold voltage.

### General Overview

As described above, DC to DC power convertors often utilize some form of voltage supervision of the input voltage, which may include elements such as a POR circuit, a bandgap voltage monitor, and an under-voltage lockout circuit. The POR circuit is used to ensure that the input voltage does not drop too low, as a low input voltage may cause the power converter to not operate correctly. For ultra-low IQ power converters (e.g. IQ between a few 10s of nA to a few 100s of nA) that are designed to operate at low voltages (e.g. between 1.6V to 1.8V), the POR circuit is incapable of detecting very fast drops to the input voltage (e.g., a falling slew of around 1V/μs), such as during a brown-out event. To compensate for this deficiency, control signals from other voltage circuits may be utilized, which does not make the POR circuit self-contained, thereby increasing both the design complexity and vulnerability.

Thus, in accordance with some embodiments of the present disclosure, a voltage monitoring circuit is disclosed that includes a built-in brown-out detection circuit to assert a reset signal in response to a brown-out condition as well as a POR circuit for asserting the reset signal when the input voltage falls below a threshold. The voltage monitoring circuit may be used with a power convertor to disable the power converter if the input voltage becomes too low. Each of the POR circuit and the brown-out detection circuit may be coupled between an input supply voltage terminal and an output control voltage terminal. The output control voltage terminal may have a logic HIGH voltage level when the input voltage is above some threshold for successful operation of the power converter and may be pulled to a ground potential (e.g., a logic LOW level) when the input voltage falls below the threshold.

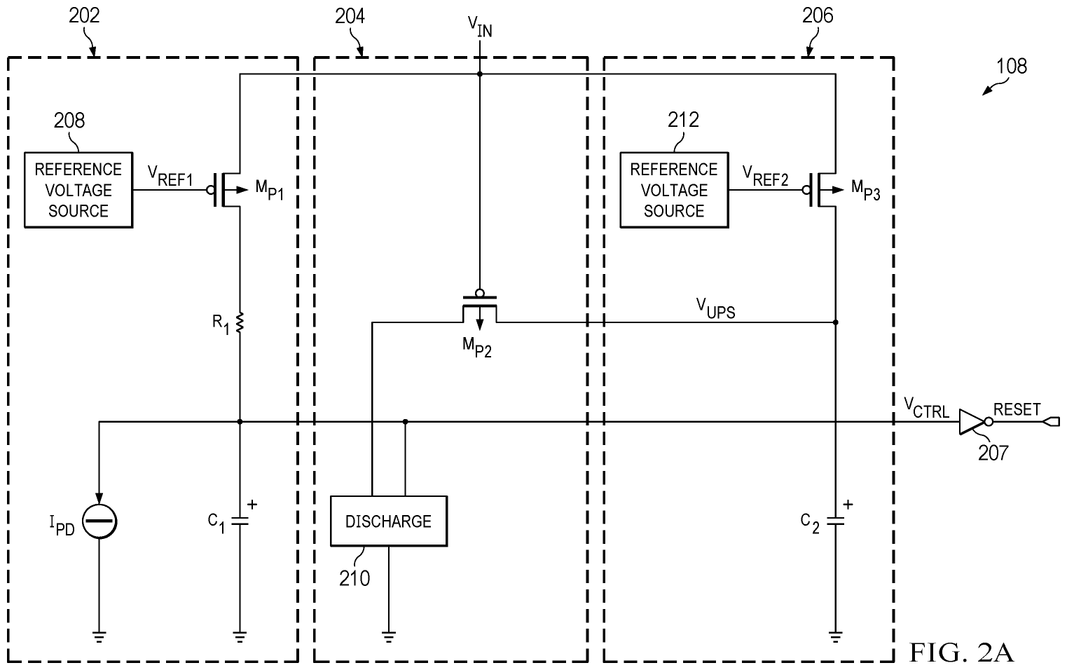

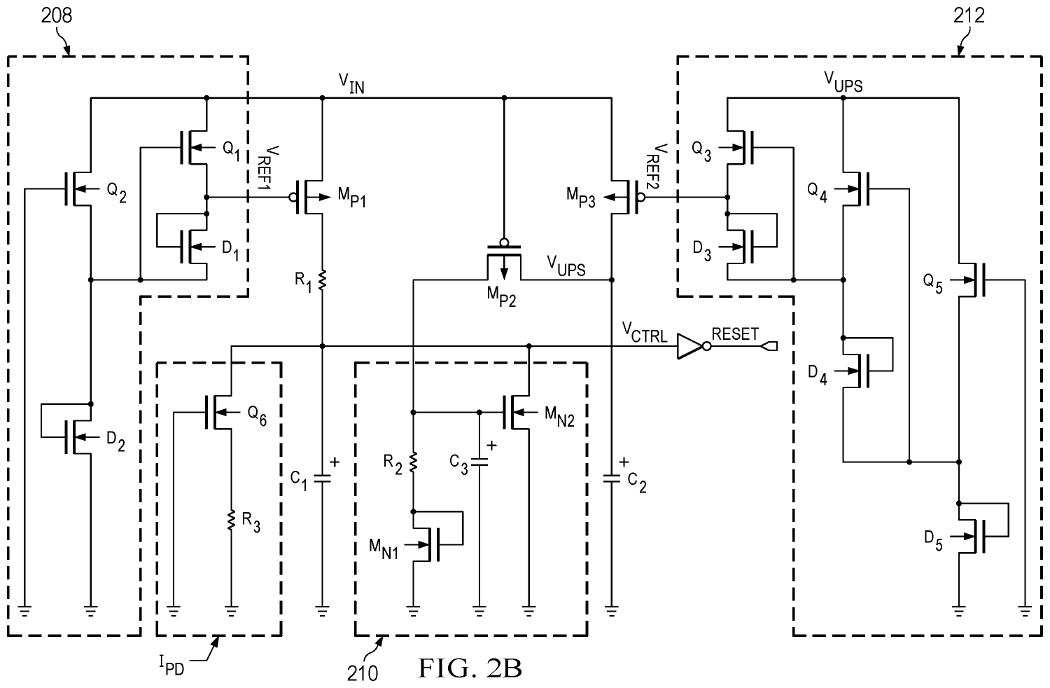

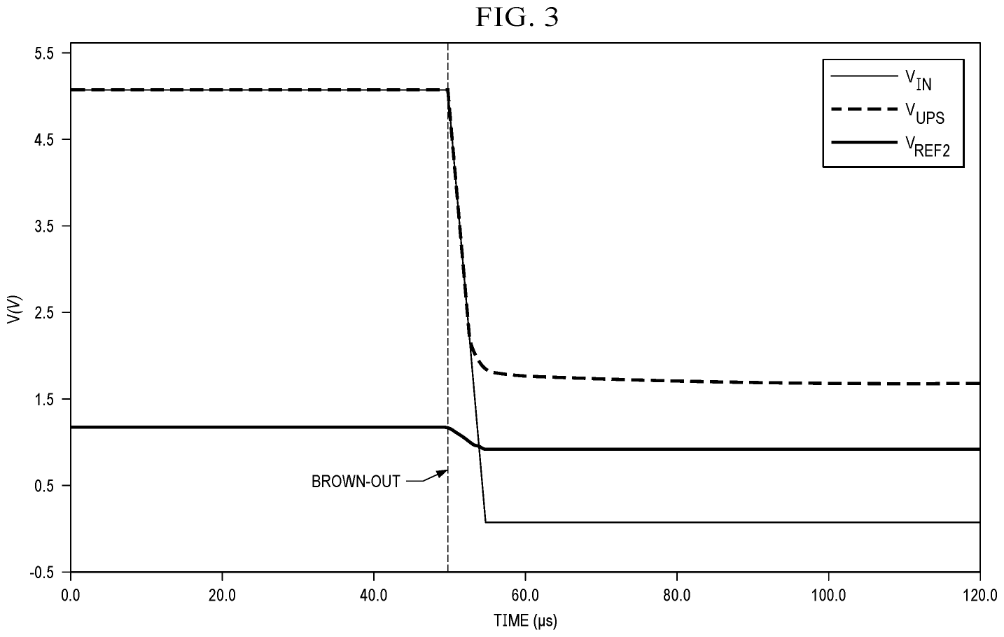

According to some embodiments, the POR circuit uses a reference voltage source coupled to the gate terminal of a first transistor and the input voltage terminal coupled to a first source or drain terminal of the first transistor. The second source or drain terminal of the first transistor is coupled to the output control voltage terminal via a resistor, according to some embodiments. The voltage on the output control voltage terminal may be brought to a logic LOW level in response to the input voltage falling below a threshold voltage that is roughly equal to the sum of the reference voltage generated by the reference voltage source and the voltage drop across the source-gate junction of the first transistor, according to some embodiments. The source-gate voltage allows the first transistor to output a current to be roughly equal to I_{PD} in saturation (as discussed in more detail with reference to FIGS. 2 and 3), according to some embodiments.

The brown-out detection circuit may include a second transistor having a gate terminal coupled to the voltage input terminal, a first source or drain terminal coupled to a backup supply voltage terminal and a second source or drain terminal coupled to a discharge circuit. The discharge circuit may have an output coupled to the output control voltage terminal and be designed to pull the output control voltage terminal to a ground potential in response to receiving a backup supply voltage from the backup supply voltage terminal when the second transistor is turned on. The backup supply voltage terminal may be coupled to a capacitor and to a first source or drain terminal of a third transistor. A second source or drain terminal of the third transistor may be coupled to the input voltage terminal while the control terminal of the third transistor is coupled to another reference voltage source, according to some embodiments.

Numerous other variations will be apparent based on the embodiments described herein.

### Electronic System

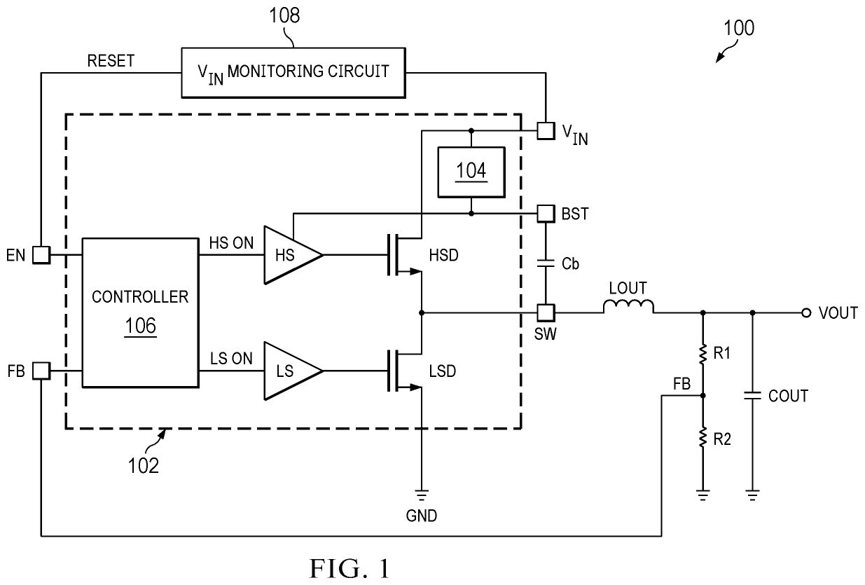

FIG. 1 illustrates at least a portion of an example electronic system 100. In some cases, electronic system 100 is implemented as a system-on-chip, or as a chip set populated on a printed circuit board (PCB), or as a set of discrete components populated on a PCB, which may in turn be populated into a chassis of a multi-chassis system or an otherwise higher-level system, although any number of implementations can be used. Electronic system 100 may be part of a switching regulator or power converter, such as a DC-DC buck switching converter.

According to some embodiments, electronic system 100 includes a power converter circuit 102, which may be implemented as a chip within a chip package and may have various input/output (I/O) terminals, such as an enable terminal (EN), a power input terminal (VIN), a bootstrap terminal (BST), a switching node terminal (SW), a ground terminal (GND), and a feedback terminal (FB). Any number of other I/O terminals may be provided.

According to some embodiments, power converter circuit 102 includes a high-side switching element (HSD) along with an associated high-side driver (HS) and a low-side switching element (LSD) along with an associated low-side driver (LS). As shown in FIG. 1, both high-side switching element HSD and low-side switching element LSD may be n-channel MOSFETs, although other suitable switching elements may be used. High-side switching element HSD has a first terminal coupled to an input power rail (e.g., V_{IN} terminal) and a second terminal coupled to the switching node SW of the power converter. Accordingly, the state of high-side driver HS controls the gate terminal of high-side switching element HSD and high-side switching element HSD provides the input voltage on V_{IN} to switching node SW when the high-side switching element HSD is on. Low-side switching element LSD has a first terminal coupled to the switching node SW and a second terminal coupled to a ground rail (e.g., at ground terminal GND). The ground terminal GND may be a global ground associated with the chip that includes power converter circuit 102. The state of low-side driver LS controls the gate terminal of low-side switching element LSD and low-side switching element LSD provides a ground voltage to switching node SW when the low-side switching element LSD is on. Only one of HSD and LSD can be on at any given time and LSD is off whenever HSD is on and vice versa.

A boost capacitor Cb may be coupled between the switching node SW and bootstrap terminal BST (or a bootstrap voltage rail) and can be used to provide a boosted voltage that is higher than the output switching voltage at SW in conjunction with a bootstrap charging circuit 104 (e.g., used to charge Cb) between bootstrap terminal BST and input voltage terminal V_{IN}. This boosted voltage may then be provided to the positive supply rail of the high-side driver HS.

An inductor LOUT may be provided at the switching node SW to smooth out the changing voltage and provide a more stable output voltage as VOUT. In some cases, inductor LOUT may be, for example, part of a transformer, or any other suitable energy storage element. A voltage divider that includes resistors R1 and R2 may be provided at the output to generate a feedback voltage that is fed to feedback terminal FB of power converter circuit 102.

A controller 106 provides control signals (e.g., HSₒₙ, and LSₒₙ) to the inputs of high-side driver HS and low-side driver LS, respectively. These control signals may be pulse width modulated signals that drive the respective high-side and low-side switching elements. Controller 106 may also receive various inputs (e.g., the feedback voltage on feedback terminal FB) to facilitate the generation of the control signals via an internal pulse width modulation circuit. According to some embodiments, the pulse width modulation circuit of controller 106 determines a duty cycle of both control signals HSₒₙ and LSₒₙ based at least on a comparison between an internal reference voltage and the feedback voltage received on feedback terminal FB.

According to some embodiments, electronic system 100 also includes a voltage monitoring circuit 108 coupled to the input voltage terminal V_{IN}. Voltage monitoring circuit 108 may be configured to monitor the voltage level of the input voltage terminal V_{IN} and assert an output reset signal in response to a voltage level on the input voltage terminal V_{IN} falling below a threshold. In some examples, the reset signal is received by an enable terminal coupled to controller 106 and the state of reset signal determines whether controller 106 operates or not. In an example, where the voltage level on the input voltage terminal V_{IN} falls below the threshold, voltage monitoring circuit 108 may assert the reset signal to disable operation of controller 106. According to some embodiments, voltage monitoring circuit 108 is designed to respond to a fast drop in the voltage level of the input voltage terminal V_{IN}, such as during a brown-out event. It should be understood that voltage monitoring circuit 108 may be integrated within controller 106, such that it is provided on the same die as controller 106. In some other examples, voltage monitoring circuit 108 is provided on a separate die from controller 106 and/or power converter circuit 102.

FIG. 2A illustrates a diagram of voltage monitoring circuit 108, according to some embodiments. Voltage monitoring circuit 108 includes a POR circuit 202, a brown-out detection circuit 204, a supply circuit 206, and an output circuit 207. According to some embodiments, POR circuit 202 may be designed to toggle the logic voltage level of output control voltage terminal V_{CTRL} in response to the voltage level of the input voltage terminal V_{IN} falling below a first threshold at a first rate while brown-out detection circuit 204 may be designed to toggle the logic voltage level of output control voltage terminal V_{CTRL} in response to the voltage level of the input voltage terminal V_{IN} falling below a second threshold at a second rate faster than the first rate (e.g., during a brown-out event). In some examples, the second rate may be a voltage drop of around 1 V/μs or greater. The first and second thresholds may be designed to be around the same voltage level.

According to some embodiments, POR circuit 202 is coupled between the input voltage terminal V_{IN} and an output control voltage terminal (V_{CTRL}). According to some embodiments, the voltage level of output control voltage terminal V_{CTRL} may be brought to a logic LOW level (e.g., grounded) in response to the voltage level of the input voltage terminal V_{IN} falling below the first threshold.

According to some embodiments, POR circuit 202 includes a transistor M_{P1} having a gate terminal coupled to a first reference voltage source 208, a first source/drain terminal coupled to the input voltage terminal V_{IN} and a second source/drain terminal coupled to the output control voltage terminal V_{CTRL} via a resistor R₁. First reference voltage source 208 may provide a reference voltage V_{REF1} that is generated based on V_{IN}. When V_{IN} falls below the first threshold, M_{P1} turns off and the current I_{PD} pulls down the potential on output control voltage terminal V_{CTRL}. The first threshold V_{POR} may be determined by the expression:

$${V}_{POR} = {V}_{RRF 1} + \vert {V}_{GS \_ MP 1} \vert \qquad ( 1 )$$

Where V_{GS_MP1} is the voltage drop across the gate and source terminals of transistor M_{P1}. The value of V_{GS_MP1} depends on the physical parameters of transistor M_{P1} and may be determined by the expression:

$${I}_{P D} = μ \cdot {C}_{o x} \cdot \frac{{W}_{MP 1}}{{L}_{MP 1}} \cdot ( n - 1 ) \cdot {V}_{T}^{2} \cdot {e}^{\frac{{V}_{GS\_MP 1} - {V}_{TH\_MP 1}}{n \cdot {V}_{T}}} \qquad ( 2 )$$

Where I_{PD} is the value of the pull-down current source, Cₒₓ is the capacitance from the gate oxide of Mₚ₁, W_{MP1} is the gate width of M_{P1}, L_{MP1} is the gate length of M_{P1}, and V_{T} is the thermal voltage. The time to pull down the potential of the output control voltage terminal V_{CTRL} may be scaled by the value of IPD.

According to some embodiments, the brown-out detection circuit 204 includes another transistor M_{P2} having a gate terminal coupled to the input voltage terminal V_{IN}, a first source/drain terminal coupled to a backup supply terminal V_{UPS}, and a second source/drain terminal coupled to a discharge circuit 210. According to some embodiments, the supply voltage on backup supply terminal V_{UPS} remains at some positive voltage level for a certain period of time even after the voltage level of input voltage terminal V_{IN} falls to zero (e.g., a brown out condition). Accordingly, the backup supply voltage may be used to activate discharge circuit 210 even in the absence of V_{IN}. According to some embodiments, discharge circuit 210 may be arranged to pull output control voltage terminal V_{CTRL} to a ground potential or a logic LOW voltage level in response to M_{P2} turning on and receiving the backup supply voltage on backup supply terminal V_{UPS} across M_{P2}. Additional details of discharge circuit 210 are provided with reference to FIG. 2B.

Supply circuit 206 includes elements to generate a backup supply voltage on backup supply terminal V_{UPS}, according to some embodiments. For example, supply circuit 206 includes another transistor M_{P3} having a gate terminal coupled to a second reference voltage source 212, a first source/drain terminal coupled to the input voltage terminal V_{IN} and a second source/drain terminal coupled to the backup supply terminal V_{UPS}. A capacitor C₂ may also be coupled between the backup supply terminal V_{UPS} and ground. According to some embodiments, the backup supply voltage on V_{UPS} is charged to the value of V_{IN} across capacitor C₂ while M_{P3} operates in the triode region. During a brown-out event, the voltage on input voltage terminal V_{IN} falls quickly to zero (or near zero), thus turning on transistor M_{P2} and also discharging the stored potential on backup supply terminal V_{UPS}. However, the V_{UPS} voltage will level off at a value determined by the expression:

$${V}_{UPS} = {V}_{REF 2} + \vert {V}_{{TH \_ M}_{P 3}} \vert \qquad ( 3 )$$

According to some embodiments, the quick fall of the voltage on V_{IN} during a brown-out event may be directly sensed by transistor M_{P2}, thus activating discharge circuit 210 when the voltage falls below the second threshold V_{POR_BO} determined by the expression:

$${V}_{POR \_ BO} = {V}_{RRF 2} + \vert {V}_{{TH \_ M}_{P 3}} \vert - \vert {V}_{{TH}_{{M}_{P 2}}} \vert \qquad ( 4 )$$

By adjusting the values of V_{REF1} and V_{REF2}, the two threshold voltages V_{POR} and V_{POR_BO}, as provided by Equations 1 and 4 above, can be made substantially equal to one another.

The output control voltage terminal V_{CTRL} may be coupled to output circuit 207 for generating a reset signal that can be received by controller 106 (or any other related circuit) to disable operation of power converter circuit 102. Output circuit 207 may include a Schmidt trigger or an inverter circuit to produce the reset signal. In the illustrated embodiment, the reset signal is toggled to a logic HIGH level to disable the operation of power converter circuit 102. In other examples, reset signal may be toggled to a logic LOW level to disable the operation of power converter circuit 102.

FIG. 2B illustrates a more detailed diagram of voltage monitoring circuit 108, according to some embodiments. Example designs of first reference voltage source 208, discharge circuit 210, and second reference voltage source 212 are illustrated.

First reference voltage source 208 and second reference voltage source 212 includes any number of cascading transistor pairs Qₓ and Dₓ that operate in the sub-threshold regime, according to some embodiments. Each Q transistor (e.g., Q₁-Q₅) may be a native transistor with a threshold voltage of substantially 0, while each D transistor (e.g., D₁-D₅) may be a transistor arranged in a diode-configuration where each D transistor has its drain terminal couped to its gate terminal. First reference voltage source 208 is arranged to provide V_{REF1} based on the voltage of V_{IN} and second reference voltage source 212 is arranged to provide V_{REF2} based on the backup voltage of V_{UPS}, according to some embodiments. Each of transistors Q₁-Q₅ and D₁-D₅ may be n-channel transistors, according to some embodiments. Any of the diode-configured transistors D₁-D₅ may be replaced with a two-terminal diode, according to some embodiments.

According to some embodiments, discharge circuit 210 includes a first transistor M_{N1} arranged in a diode-configuration and coupled in series with another resistor R₂. Accordingly, a gate terminal of M_{N1} may be coupled to a first source/drain terminal of M_{N1} while a first terminal of R₂ is coupled to the first source/drain terminal of M_{N1} and a second terminal of R₂ is coupled to the gate terminal of another transistor M_{N2}. The gate terminal of M_{N2} is coupled to the second source/drain terminal of M_{P2} and thus receives the backup voltage from V_{UPS} when M_{P2} is turned on during a brown-out event. The receipt of the backup voltage V_{UPS} at the gate terminal of M_{N2} turns on M_{N2} to pull output voltage control terminal V_{CTRL} to ground. According to some embodiments, a capacitor C₃ may also be coupled between the gate terminal of M_{N2} and ground.

Each of transistors M_{N1} and M_{N2} may be n-channel transistors. According to some embodiments, the threshold voltage of M_{N1} may be lower than the threshold voltage of M_{N2}.

According to some embodiments, the current source I_{PD} may be represented by another native transistor (Q₆) coupled in series with a resistor R₃. For example, a first source/drain terminal of transistor Q₆ is coupled to output voltage control terminal V_{CTRL}, a second source/drain terminal of Q₆ is coupled to a first terminal of resistor R₃, a gate terminal of Q₆ is coupled to ground, and a second terminal of resistor R₃ is coupled to ground.

FIG. 3 illustrates a line plot of various voltages over time from voltage monitoring circuit 108 during a brown out event, according to some embodiments. Before the brown-out event occurs, the backup voltage level at V_{UPS} is substantially equal to the input voltage level at V_{IN}. Furthermore, V_{REF2} is set at some consistent level that is a pre-determined fraction of V_{UPS} depending on the design of second reference voltage source 212. At the onset of the brown-out event at around the 50 μs mark, the voltage on V_{IN} sharply falls to 0. The backup voltage V_{UPS} also drops, but stops at a voltage level (e.g., around 1.5 V in the illustrated example) based on the value of V_{REF2} as provided by equation 3 above. Second reference voltage source 212 remains relatively stable following the brown-out event and only experiences a small drop in potential, according to some embodiments.

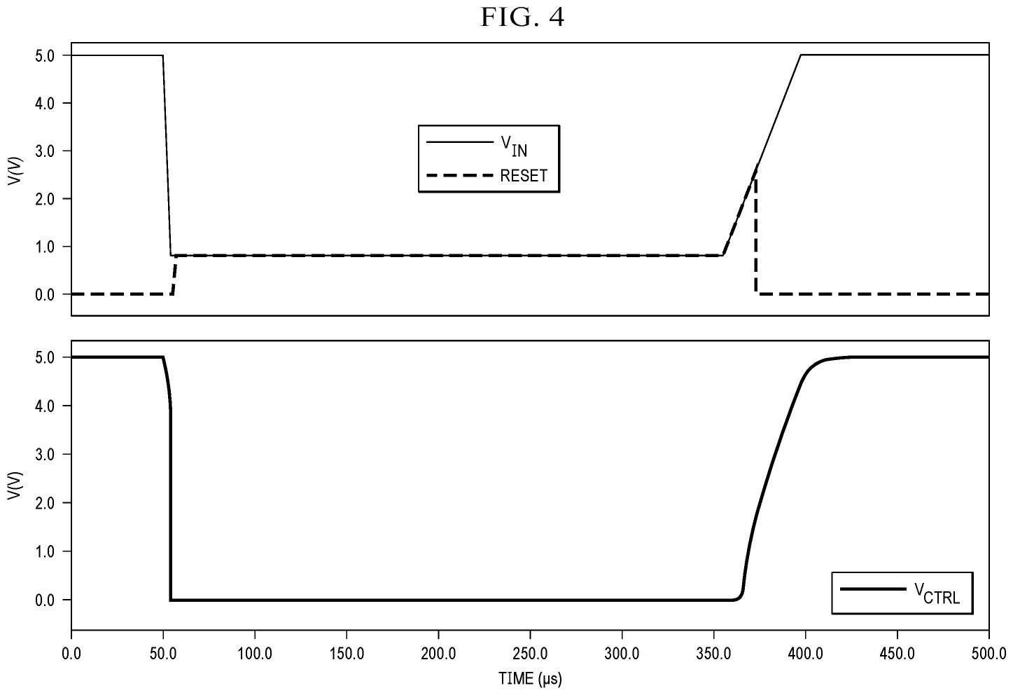

FIG. 4 illustrates additional line plots of various voltage levels over time from voltage monitoring circuit 108 during a brown out event, according to some embodiments. The brown-out event occurs around the 50 μs mark. As shown previously, the voltage level on V_{IN} falls sharply at the onset of the brown-out event. The sharp decline of V_{IN} activates discharge circuit 210 which quickly pulls the output voltage control terminal V_{CTRL} to ground as shown in the lower plot. The sharp decrease of the potential on V_{CTRL} causes the reset signal to be asserted to some positive voltage level above 0 (e.g., around 1 V in the illustrated example). At some later point in time (e.g., around 350 μs in the illustrated example), the voltage on V_{IN} begins to rise back to its original level or to some other operational level. The increase of the voltage level on V_{IN} eventually turns off transistor M_{P}n, effectively deactivating discharge circuit 210 and allowing the potential on V_{CTRL} to rise back to a level around that of V_{IN} (or some other suitable operating level). Once the potential on output voltage control terminal V_{CTRL} rises high enough, the reset signal is unasserted back to a logic LOW level (e.g., around 0 volts), and the power converter is once again allowed to operate normally.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs). Moreover, reference to transistor features such as gate, source, or drain is not intended to exclude any suitable transistor technologies. For instance, features such as source, drain, and gate are typically used to refer to a FET, while emitter, collector, and base are typically used to refer to a BJT. Such features may be used interchangeably herein. For instance, reference to the gate of a transistor may refer to either the gate of a FET or the base of a BJT, and vice-versa. In some examples, a control terminal may refer to either the gate of a FET or the base of a BJT. Any other suitable transistor technologies can be used. Any such transistors can be used as a switch, with the gate or base or other comparable feature acting as a switch select input that can be driven to connect the source and drain (or the emitter and collector, as the case may be).

References herein to a field effect transistor (FET) being “ON” (or a switch being closed) means that the conduction channel of the FET is present, and drain current may flow through the FET. References herein to a FET being “OFF” (or a switch being open) means that the conduction channel is not present, and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

### Further Examples

Example 1 is a circuit that includes an input supply voltage terminal, an output control voltage terminal, a power-on-reset (POR) circuit coupled to the input supply voltage terminal, and a brown-out detection circuit coupled to the input supply voltage terminal and the output control voltage terminal. The POR circuit includes a POR circuit output coupled to the output control voltage terminal. The brown-out detection circuit includes a back-up supply voltage input. The brown-out detection circuit is configured to discharge the output control voltage terminal to a reset state, responsive to a difference in potential between the back-up supply voltage input and the input supply voltage terminal exceeding a threshold voltage.

Example 2 includes the circuit of Example 1, where the POR circuit includes a reference voltage source, a first transistor having a first current terminal, a second current terminal, and a control terminal, with the first current terminal of the first transistor coupled to the input supply voltage terminal and the control terminal of the first transistor coupled to the reference voltage source, a resistor coupled between the second current terminal of the first transistor and the output control voltage terminal, and a capacitor coupled between the output control voltage terminal and a ground terminal. The brown-out detection circuit includes a second transistor having a first current terminal, a second current terminal, and a control terminal, with the control terminal of the second transistor coupled to the input supply voltage terminal, and the first current terminal of the second transistor coupled to the back-up supply voltage input, and a discharge circuit coupled to the second current terminal of the second transistor and to the output control voltage terminal.

Example 3 includes the circuit of Example 2, wherein the reference voltage source is a first reference voltage source, the capacitor is a first capacitor, and the circuit further comprises a back-up supply voltage circuit that includes a third transistor having a first current terminal, a second current terminal, and a control terminal, with the first current terminal of the third transistor coupled to the input supply voltage terminal, the control terminal of the third transistor coupled to a second reference voltage source, and the second current terminal of the third transistor coupled to the back-up supply voltage input of the brown-out detection circuit, and a second capacitor coupled between the back-up supply voltage input of the brown-out detection circuit and the ground terminal.

Example 4 includes the circuit of Example 3, wherein each of the first transistor, second transistor, and third transistor is a PMOS transistor.

Example 5 includes the circuit of Example 3 or 4, further comprising a third capacitor coupled between the second current terminal of the second transistor and the ground terminal.

Example 6 includes the circuit of any one of Examples 3-5, wherein the resistor is a first resistor, and the discharge circuit comprises a second resistor and a diode circuit coupled in series with one another between the second current terminal of the second transistor and the ground terminal.

Example 7 includes the circuit of Example 6, wherein the diode circuit includes a diode or a diode-connected transistor.

Example 8 includes the circuit of Example 6 or 7, wherein the discharge circuit comprises a fourth transistor having a first current terminal, a second current terminal, and a control terminal, with the first current terminal of the fourth transistor coupled to the output control voltage terminal, the second current terminal of the fourth transistor coupled to the ground terminal; and the control terminal of the fourth transistor coupled to the second current terminal of the second transistor.

Example 9 includes the circuit of Example 8, wherein a threshold voltage of the diode circuit is lower than a threshold voltage of the fourth transistor.

Example 10 includes the circuit of any one of Examples 1-9, further comprising an output circuit having its input coupled to the output control voltage terminal and configured to generate a reset signal based on a state of the output control voltage terminal.

Example 11 includes the circuit of Example 10, wherein the output circuit comprises a Schmidt trigger circuit.

Example 12 includes the circuit of Example 10, wherein the output circuit comprises an inverter circuit.

Example 13 includes the circuit of any one of Examples 1-12, wherein the POR circuit includes a current source coupled to the output control voltage terminal.

Example 14 includes the circuit of Example 13, wherein the current source comprises a native transistor having a first current terminal coupled to the output control voltage terminal and a second current terminal coupled to a ground terminal via a resistor.

Example 15 is an integrated circuit that includes the circuit of any one of Examples 1-14.

Example 16 is a power converter that includes the circuit of any one of Examples 1-14.

Example 17 includes the power converter of Example 16, wherein the power converter is a DC-to-DC power converter.

Example 18 is a controller that includes a pulse width modulation circuit configured to determine a switching element duty cycle for a power converter based on a comparison between a reference voltage and a feedback voltage representative of an output voltage of the power converter, and a voltage monitoring circuit. The voltage monitoring circuit includes a reset block, a brown-out detection block, a supply block, and an output circuit. The reset block includes a first transistor coupled between an input supply voltage terminal and a resistor with the resistor coupled between the first transistor and a control output. The brown-out detection block includes a second transistor and a discharge module. The second transistor has a control terminal coupled to the input supply voltage terminal, and the discharge module is configured to discharge voltage at the control output to a ground terminal. The supply block has a third transistor coupled to the input supply voltage terminal and to the second transistor. The output circuit is coupled to the control output and is configured to provide an enable signal for the controller.

Example 19 includes the controller of Example 18, wherein the reset block includes a capacitor coupled between the control output and a ground terminal.

Example 20 includes the controller of Example 18 or 19, wherein the reset block includes a current source coupled to the control output.

Example 21 includes the controller of Example 20, wherein the resistor is a first resistor, and the current source comprises a native transistor coupled between the control output and a second resistor.

Example 22 includes the controller of any one of Examples 18-21, wherein each of the first transistor, second transistor, and third transistor is a PMOS transistor.

Example 23 includes the controller of any one of Examples 18-22, wherein the resistor is a first resistor, and the discharge module comprises a second resistor coupled to the second transistor.

Example 24 includes the controller of Example 23, further comprising a capacitor coupled to the second resistor.

Example 25 includes the controller of Example 23 or 24, wherein the discharge module comprises a fourth transistor coupled to the control output and coupled to the second resistor.

Example 26 includes the controller of Example 25, further comprising a fifth transistor coupled between the second resistor and a ground terminal.

Example 27 includes the controller of Example 26, wherein a threshold voltage of the fifth transistor is lower than a threshold voltage of the fourth transistor.

Example 28 includes the controller of any one of Examples 18-27, wherein the output circuit comprises a Schmitt trigger having a first terminal coupled to the control output and a second terminal coupled to an output terminal.

Example 29 includes the controller of any one of Examples 18-27, wherein the output circuit comprises an inverter circuit.

Example 30 is a power converter circuit that includes the controller of any one of Examples 18-29, a high-side switching element coupled between the input supply voltage terminal and a switching voltage terminal, a first driver having an output coupled to a control terminal of the high-side switching element, a low-side switching element coupled between the switching voltage terminal and a ground terminal of the power converter circuit, and a second driver having an output coupled to a control terminal of the low-side switching element.

Example 31 is a voltage monitoring circuit that includes a first block configured to assert a first control signal on a control output responsive to an input voltage on an input supply voltage rail terminal falling below a first threshold at a first rate, a second block configured to assert a second control signal on the control output responsive to the input voltage on the input supply voltage rail terminal falling below a second threshold at a second rate faster than the first rate, and an output circuit coupled to the control output and configured to assert a reset signal based on the first or second control signal.

Example 32 includes the voltage monitoring circuit of Example 31, wherein the first block comprises a transistor coupled in series with a resistor.

Example 33 includes the voltage monitoring circuit of Example 32, wherein the transistor includes a first current terminal, a second current terminal, and a control terminal, with the first current terminal of the transistor coupled to the input supply voltage terminal, the control terminal of the transistor coupled to a reference source, and the second current terminal of the transistor coupled to the resistor.

Example 34 includes the voltage monitoring circuit of Example 32 or 33, wherein the resistor is coupled between the transistor and the control output.

Example 35 includes the voltage monitoring circuit of any one of Examples 31-34, further comprising a capacitor coupled between the control output and a ground rail terminal.

Example 36 includes the voltage monitoring circuit of any one of Examples 31-35, wherein the second block comprises a transistor having a gate terminal coupled to the input supply voltage terminal and a first current terminal coupled to a discharge module.

Example 37 includes the voltage monitoring circuit of Example 36, wherein the discharge module comprises a resistor coupled to the first current terminal of the transistor.

Example 38 includes the voltage monitoring circuit of Example 37, wherein the discharge module comprises a capacitor coupled between the first current terminal of the transistor and a ground rail terminal.

Example 39 includes the voltage monitoring circuit of Example 37 or 38, wherein the transistor is a first transistor and the discharge module comprises a second transistor coupled to the control output and coupled to the resistor.

Example 40 includes the voltage monitoring circuit of Example 39, further comprising a third transistor coupled between the resistor and a ground rail terminal.

Example 41 includes the voltage monitoring circuit of Example 40, wherein a threshold voltage of the third transistor is lower than a threshold voltage of the second transistor.

Example 42 includes the voltage monitoring circuit of any one of Examples 36-41, wherein the transistor is a first transistor and the second block comprises a second transistor having a control terminal coupled to a reference source, a first current terminal coupled to the input supply voltage rail terminal, and a second current terminal coupled to a second current terminal of the first transistor.

Example 43 includes the voltage monitoring circuit of Example 42, wherein the second block comprises a capacitor coupled between the second current terminal of the first transistor and a ground rail terminal.

Example 44 includes the voltage monitoring circuit of any one of Examples 31-43, wherein the output circuit comprises a Schmitt trigger.

Example 45 includes the voltage monitoring circuit of any one of Examples 31-43, wherein the output circuit comprises an inverter circuit.

Example 46 is a voltage regulator that includes the voltage monitoring circuit of any one of Examples 31-45, the input supply voltage terminal, a ground rail terminal, a feedback circuit configured to provide a feedback voltage representative of an output voltage of the voltage regulator, a first switching element coupled between the input supply voltage terminal and a switching terminal, a first driver coupled to a control terminal of the first switching element, a second switching element coupled between the switching terminal and the ground rail terminal, such that the first and second switching elements are serially connected between the input supply voltage terminal and the ground rail terminal, a second driver coupled to a control terminal of the second switching element, a reference generator circuit configured to generate a reference voltage, and a pulse width modulation circuit configured to determine a duty cycle of the first switching element and the second switching element based on a comparison between the feedback voltage and the reference voltage.

Modifications are possible in the described examples, and other examples are possible within the scope of the claims.

What is claimed is:

1. A circuit, comprising:
an input supply voltage terminal;
an output control voltage terminal;
a power-on-reset (POR) circuit coupled to the input supply voltage terminal, and including a POR circuit output coupled to the output control voltage terminal; and
a brown-out detection circuit coupled to the input supply voltage terminal and the output control voltage terminal, the brown-out detection circuit including a back-up supply voltage input and configured to discharge the output control voltage terminal to a reset state, responsive to a difference in potential between the back-up supply voltage input and the input supply voltage terminal exceeding a threshold voltage.

2. The circuit of claim 1, wherein:
the POR circuit comprises
a reference voltage source, a first transistor having a first current terminal, a second current terminal, and a control terminal, with the first current terminal of the first transistor coupled to the input supply voltage terminal and the control terminal of the first transistor coupled to the reference voltage source,
a resistor coupled between the second current terminal of the first transistor and the output control voltage terminal, and
a capacitor coupled between the output control voltage terminal and a ground terminal; and/or
the brown-out detection circuit comprises
a second transistor having a first current terminal, a second current terminal, and a control terminal, with the control terminal of the second transistor coupled to the input supply voltage terminal, and the first current terminal of the second transistor coupled to the back-up supply voltage input, and
a discharge circuit coupled to the second current terminal of the second transistor and to the output control voltage terminal.

3. The circuit of claim 2, wherein the reference voltage source is a first reference voltage source, the capacitor is a first capacitor, and the circuit further comprises a back-up supply voltage circuit that includes:
a third transistor having a first current terminal, a second current terminal, and a control terminal, with the first current terminal of the third transistor coupled to the input supply voltage terminal, the control terminal of the third transistor coupled to a second reference voltage source, and the second current terminal of the third transistor coupled to the back-up supply voltage input of the brown-out detection circuit; and
a second capacitor coupled between the back-up supply voltage input of the brown-out detection circuit and the ground terminal.

4. The circuit of claim 3, wherein the resistor is a first resistor, and the discharge circuit comprises a second resistor and a diode circuit coupled in series with one another between the second current terminal of the second transistor and the ground terminal.

5. The circuit of claim 4, wherein the discharge circuit comprises a fourth transistor having a first current terminal, a second current terminal, and a control terminal, with the first current terminal of the fourth transistor coupled to the output control voltage terminal, the second current terminal of the fourth transistor coupled to the ground terminal; and the control terminal of the fourth transistor coupled to the second current terminal of the second transistor.

6. The circuit of claim 1, further comprising an output circuit having its input coupled to the output control voltage terminal and configured to generate a reset signal based on a state of the output control voltage terminal.

7. A DC-to-DC power converter comprising the circuit of claim 1.

8. A controller, comprising:
a pulse width modulation circuit configured to determine a switching element duty cycle for a power converter based on a comparison between a reference voltage and a feedback voltage representative of an output voltage of the power converter; and
a voltage monitoring circuit comprising
a reset block including a first transistor coupled between an input supply voltage terminal and a resistor, with the resistor coupled between the first transistor and a control output,
a brown-out detection block including a second transistor and a discharge module, the second transistor having a control terminal coupled to the input supply voltage terminal, and the discharge module configured to discharge voltage at the control output to a ground terminal,
a supply block having a third transistor coupled to the input supply voltage terminal and to the second transistor, and
an output circuit coupled to the control output and configured to provide an enable signal for the controller.

9. The controller of claim 8, wherein the resistor is a first resistor, and the discharge module comprises a second resistor coupled to the second transistor.

10. The controller of claim 9, wherein the discharge module comprises a fourth transistor coupled to the control output and coupled to the second resistor.

11. The controller of claim 10, further comprising a fifth transistor coupled between the second resistor and a ground terminal.

12. The controller of claim 11, wherein a threshold voltage of the fifth transistor is lower than a threshold voltage of the fourth transistor.

13. The controller of claim 8, wherein the output circuit comprises a Schmitt trigger having a first terminal coupled to the control output and a second terminal coupled to an output terminal.

14. A voltage monitoring circuit comprising:
a first block configured to assert a first control signal on a control output, responsive to an input voltage on an input supply voltage terminal falling below a first threshold at a first rate;
a second block configured to assert a second control signal on the control output, responsive to the input voltage on the input supply voltage terminal falling below a second threshold at a second rate faster than the first rate; and
an output circuit coupled to the control output and configured to assert a reset signal based on the first or second control signal.

15. The voltage monitoring circuit of claim 14, wherein the first block comprises a transistor coupled in series with a resistor.

16. The voltage monitoring circuit of claim 14, further comprising a capacitor coupled between the control output and a ground rail terminal.

17. The voltage monitoring circuit of claim 14, wherein the second block comprises a transistor having a gate terminal coupled to the input supply voltage terminal and a first current terminal coupled to a discharge module.

18. The voltage monitoring circuit of claim 17, wherein the transistor is a first transistor, and the second block comprises a second transistor having a control terminal coupled to a reference source, a first current terminal coupled to the input supply voltage terminal, and a second current terminal coupled to a second current terminal of the first transistor.

19. The voltage monitoring circuit of claim 18, wherein the second block comprises a capacitor coupled between the second current terminal of the first transistor and a ground rail terminal.

20. A voltage regulator, comprising:
the voltage monitoring circuit of claim 14;
the input supply voltage terminal;
a ground rail terminal;
a feedback circuit configured to provide a feedback voltage representative of an output voltage of the voltage regulator;
a first switching element coupled between the input supply voltage terminal and a switching terminal;
a first driver coupled to a control terminal of the first switching element;
a second switching element coupled between the switching terminal and the ground rail terminal, such that the first and second switching elements are serially connected between the input supply voltage terminal and the ground rail terminal;
a second driver coupled to a control terminal of the second switching element;
a reference generator circuit configured to generate a reference voltage; and
a pulse width modulation circuit configured to determine a duty cycle of the first switching element and the second switching element based on a comparison between the feedback voltage and the reference voltage.
